(19) United States
(12) Patent Application Publication
(10) Pub. No.: US 2010/0147364 A1
(43) Pub. Date: Jun. 17, 2010

(54) THIN FILM PHOTOVOLTAIC MODULE MANUFACTURING METHODS AND STRUCTURES

(75) Inventors: Pedro Gonzalez, San Jose, CA (US); Bulent M. Basol, Manhattan Beach, CA (US); Burak Metin, Milpitas, CA (US); Mukundan Narasimhan, San Jose, CA (US); Mustafa Pinarbasi, Morgan Hill, CA (US)

Correspondence Address: PILLSBURY WINTHROP SHAW PITTMAN LLP, P.O. BOX 10500, MCLEAN, VA, 22102, US

(73) Assignee: SoloPower, Inc., San Jose, CA (US)

(21) Appl. No.: 12/639,658

(22) Filed: Dec. 16, 2009

Related U.S. Application Data
(60) Provisional application No. 61/138,116, filed on Dec. 16, 2008.
(60) Provisional application No. 61/141,452, filed on Dec. 30, 2008.

(51) Int. Cl. H01L 31/048; H01L 31/0203

(52) U.S. Cl. 136/251; 438/59; 257/E31.117

(57) ABSTRACT

The present invention provides module structures and methods of manufacturing rigid or flexible photovoltaic modules employing thin film solar cells fabricated on flexible substrates, preferably on flexible metallic foil substrates. The solar cells may be Group IBIIIAVIA compound solar cells or amorphous silicon solar cells fabricated on thin stainless steel or aluminum alloy foils. In one embodiment, initially a solar cell string including two or more solar cells is formed by interconnecting the solar cells with conductive leads or ribbons. At least one bypass diode electrically connects conductive back surfaces of at least two solar cells. The bypass diode and the solar cells are encapsulated with support material and are packed with the protective shell such that the at least one bypass diode is placed between at least one solar cell and the bottom protective sheet. The bypass diode is thermally connected to the back conductive surface of one of the solar cells so that the back conductive surface of the solar cell functions as a heat sink.

### CROSS REFERENCE TO RELATED APPLICATIONS

This application claims priority and is related to U.S. provisional application No. 61/138,116 filed Dec. 16, 2008 and U.S. provisional application No. 61/141,452 filed Dec. 20, 2008, both of which are incorporated herein by reference.

### FIELD OF THE INVENTIONS

The aspects and advantages of the present inventions generally relate to photovoltaic or solar module design and fabrication and, more particularly, to modules utilizing thin film solar cells.

### DESCRIPTION OF THE RELATED ART

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors comprising some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ(S_{y}Se_{1-y})ₖ, where 0≦x≦1, 0≦y≦1 and k is approximately 2, have already been employed in solar cell structures that yielded conversion efficiencies approaching 20%. Therefore, in summary, compounds containing: i) Cu from Group IB, ii) at least one of In, Ga, and Al from Group IIIA, and iii) at least one of S, Se, and Te from Group VIA, are of great interest for solar cell applications. It should be noted that although the chemical formula for CIGS(S) is often written as Cu(In,Ga)(S,Se)₂, a more accurate formula for the compound is Cu(In,Ga)(S,Se)ₖ, where k is typically close to 2 but may not be exactly 2. For simplicity we will continue to use the value of k as 2. It should be further noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

The structure of a Group IBIIIAVIA compound photovoltaic cell such as a Cu(In,Ga,Al)(S,Se,Te)₂ thin film solar cell is shown in FIG. 1. A photovoltaic cell 10 is fabricated on a substrate 11, such as a sheet of glass, a sheet of metal, an insulating foil or web, or a conductive foil or web. An absorber film 12, which includes a material in the family of Cu(In,Ga,Al)(S,Se,Te)₂, is grown over a conductive layer 13 or contact layer, which is previously deposited on the substrate 11 and which acts as the electrical contact to the device. The substrate 11 and the conductive layer 13 form a base 20 on which the absorber film 12 is formed. Various conductive layers comprising Mo, Ta, W, Ti, and their nitrides have been used in the solar cell structure of FIG. 1. If the substrate itself is a properly selected conductive material, it is possible not to use the conductive layer 13, since the substrate 11 may then be used as the ohmic contact to the device. After the absorber film 12 is grown, a transparent layer 14 such as a CdS, ZnO, CdS/ZnO or CdS/ZnO/ITO stack is formed on the absorber film 12. Radiation 15 enters the device through the transparent layer 14. Metallic grids (not shown) may also be deposited over the transparent layer 14 to reduce the effective series resistance of the device. The preferred electrical type of the absorber film 12 is p-type, and the preferred electrical type of the transparent layer 14 is n-type. However, an n-type absorber and a p-type window layer can also be utilized. The preferred device structure of FIG. 1 is called a “substrate-type” structure. A “superstrate-type” structure can also be constructed by depositing a transparent conductive layer on a transparent superstrate such as glass or transparent polymeric foil, and then depositing the Cu(In,Ga,Al)(S,Se,Te)₂ absorber film, and finally forming an ohmic contact to the device by a conductive layer. In this superstrate structure light enters the device from the transparent superstrate side.

There are two different approaches for manufacturing PV modules. In one approach that is applicable to thin film CdTe, amorphous Si and CIGS technologies, the solar cells are deposited or formed on an insulating substrate such as glass that also serves as a back protective sheet or a front protective sheet, depending upon whether the device is “substrate-type” or “superstrate-type”, respectively. In this case the solar cells are electrically interconnected as they are deposited on the substrate. In other words, the solar cells are monolithically integrated on the single-piece substrate as they are formed. These modules are monolithically integrated structures. For CdTe thin film technology the superstrate is glass which also is the front protective sheet for the monolithically integrated module. In CIGS technology the substrate is glass or polyimide and serves as the back protective sheet for the monolithically integrated module. In monolithically integrated module structures, after the formation of solar cells which are already integrated and electrically interconnected in series on the substrate or superstrate, an encapsulant is placed over the integrated module structure and a protective sheet is attached to the encapsulant. An edge seal may also be formed along the edge of the module to prevent water vapor or liquid transmission through the edge into the monolithically integrated module structure.

In standard single or polycrystalline Si module technologies, and for CIGS and amorphous Si cells that are fabricated on conductive substrates such as aluminum or stainless steel foils, the solar cells are not deposited or formed on the protective sheet. They are separately manufactured and then the manufactured solar cells are electrically interconnected by stringing them or shingling them to form solar cell strings. In the stringing or shingling process, the (+) terminal of one cell is typically electrically connected to the (−) terminal of the adjacent device. For the Group IBIIIAVIA compound solar cell shown in FIG. 1, if the substrate 11 is conductive such as a metallic foil, then the substrate, which is the bottom contact of the cell, constitutes the (+) terminal of the device. The metallic grid (not shown) deposited on the transparent layer 14 is the top contact of the device and constitutes the (−) terminal of the cell. In shingling, individual cells are placed in a staggered manner so that a bottom surface of one cell, i.e. the (+) terminal, makes direct physical and electrical contact to a top surface, i.e. the (−) terminal, of an adjacent cell. Therefore, there is no gap between two shingled cells. In contrast, for solar cells that are strung together as exemplified in FIG. 2A with a PV module 50, solar cells 52 are placed side by side with a small gap (typically 1-2 mm) between them and using conductive wires 54 or ribbons that connect the (+) terminal of one cell to the (−) terminal of an adjacent cell. Solar cell strings obtained by stringing (or shingling) individual solar cells are interconnected through “busing” or “bussing” to form circuits. Circuits may then be packaged in protective shell 56 or package to seal the module 50. Each module typically includes a plurality of strings of solar cells which are electrically connected to one another.

As shown in FIG. 2B in a cross-sectional view, the PV module 50 such as shown in FIG. 2A is constructed using various packaging materials to mechanically support and protect the solar cells in it against mechanical and moisture damage. The most common packaging technology involves lamination of circuits in transparent encapsulants. In a lamination process, in general, the electrically interconnected solar cells 52 are covered with a transparent and flexible encapsulant layer 58 which fills any hollow space among the cells and tightly seals them into a module structure, preferably covering both of their surfaces. A variety of materials are used as encapsulants, for packaging solar cell modules, such as ethylene vinyl acetate copolymer (EVA), thermoplastic polyurethanes (TPU), and silicones. However, in general, such encapsulant materials are moisture permeable; therefore, they must be further sealed from the environment by a protective shell, which forms resistance to moisture transmission into the module package. The nature of the protective shell 56 determines the amount of water vapor that can enter the module 50. The protective shell 56 includes a front protective sheet 60A and a back protective sheet 60B and optionally an edge sealant 60C that is at the periphery of the module structure (see for example, published application WO/2003/050891, “Sealed Thin Film PV Modules”). The top protective sheet 60A is typically glass which is water impermeable. The back protective sheet 60B may be a sheet of glass or a polymeric sheet such as TEDLAR® (a product of DuPont) or a multi-layer laminate comprising TEDLAR. The back protective sheet 60B may or may not have a moisture barrier layer in its structure such as a metallic film like an aluminum film. Light enters the module through the front protective sheet 60A. The edge sealant 60C, which is presently used in thin film CdTe modules with glass/glass structure, is a moisture barrier material that may be in the form of a viscous fluid which may be dispensed from a nozzle to the peripheral edge of the module structure or it may be in the form of a tape which may be applied to the peripheral edge of the module structure. The edge sealant in Si-based modules is not between the top and bottom protective sheets but rather in the frame 65 which is attached to the edge of the module. Moisture barrier characteristics of the edge seals used for Si-based modules are not adequate for CIGS based modules as will be discussed later.

Flexible module structures may be constructed using flexible CIGS or amorphous Si solar cells. Flexible modules are light weight, and unlike the standard glass based Si solar modules, are un-breakable. Therefore, packaging and transportation costs for the manufactured flexible modules are much lower than for solar cell or module structures formed on glass that are not flexible and are easily damaged by mishandling. However, manufacture of flexible module structures is challenging in respects that are different from solar cell and module structures formed on glass that are not flexible. Further, while glass handling equipment used in glass based PV module manufacturing is fully developed by many equipment suppliers, handling of flexible sheets cannot be carried out using such standard equipment, and different equipment is required. Further, requirements are different for the flexible sheets that constitute the various layers in the flexible module structure. Various layers in flexible module structure may be cut into sizes that are close to the desired area of the module and encapsulation procedures may be carried out by handling and moving these pieces around. However, handling such flexible materials can cause difficulties. As such, there have been attempts to obtain a more manufacturing friendly approach for flexible module manufacturing to increase the reliability of such modules and reduce their manufacturing cost. Examples of certain approached previously proposed for flexible amorphous Si based device fabrication are described in U.S. Pat. Nos. 4,746,618, 4,773,944, 5,131,954, 5,968,287, 5,457,057 and 5,273,608.

As shown in FIGS. 2A-2B, solar cells 52 are typically interconnected in series to form circuits, which are then encapsulated to form the PV module 50. One important point relating to series connection of solar cells relates to shading of individual cells. If any one of the cells 52 in a cell string within a module is shadowed for a period, the shadowed cell may become reverse-biased due to the shadowing, in contrast to the other cells that receive light and are operational. Such reverse biasing of individual cells may cause breakdown of that cell and its overheating, and degradation of the overall module output. To avoid such problems it is customary to use bypass diodes which are placed into a junction box 62 attached to the back protective sheet 60B of the PV module 50. For standard Si technology, the reverse breakdown voltage of the Si solar cells is large enough that a bypass diode may be used for every string containing 18-24 solar cells. Therefore, in Si solar modules 1, 2, or 3 bypass diodes are typically placed into junction boxes, which are attached onto the back surface of the modules, and these diodes are connected to the appropriate points on the cell strings within the module package. The reverse breakdown voltages of thin film solar cells such as amorphous Si or CIGS devices fabricated on flexible metallic substrates are much lower than those of Si solar cells. CIGS devices, for example, may display a reverse breakdown voltage in the range of 1-6V, compared to Si solar cells which typically have breakdown voltages more than 10V. This means that, high power thin film solar modules such as over 100 W CIGS modules may need more than 10 bypass diodes to properly protect the cells and assure that module performs safely without hot spots. It is not practical to place so many bypass diodes in a junction box outside the module package. Newly developed approaches (see e.g. US Patent application 2005/0224109) that place a limited number of bypass diodes along an edge of the module within the module package are not adequate for thin film type devices because, as stated above, thin film modules require the use of a large number of bypass diodes such as more than 10, even 20 bypass diodes.

### SUMMARY

The present inventions generally relate to photovoltaic or solar module design and fabrication and, more particularly, to modules utilizing thin film solar cells.

In one aspect is described a solar module, comprising: a solar cell string including a plurality of solar cells including a first solar cell and a second solar cell, each solar cell having a light receiving side and a back side, wherein the back side comprises a conductive substrate and wherein the plurality of solar cells are electrically interconnected in series using conductive leads which connect the light receiving side of one solar cell to the back side of an adjacent solar cell; a bypass diode device attached to the solar cell string, the bypass diode device including a bypass diode having a first and second leads, and first and second conductive strips each electrically connected at one end to one of the first and second leads respectively and each electrically connected at another end to a first conductive substrate of the first solar cell and a second conductive substrate of the second solar cell, respectively; an encapsulant having a frontside and a backside that encapsulates the solar cell string and the bypass diode device; and a protective shell sealing the encapsulated string, the protective shell including a transparent front protective layer, a back protective layer and a moisture barrier seal extending between and sealing edges of the transparent front protective layer and the back protective layer, wherein the transparent front protective sheet is placed over the light receiving side of the plurality solar cells and the frontside of the encapsulant and the back protective sheet is placed under the first and second conductive substrates, the by pass diode device and the backside of the encapsulant such that the bypass diode is located between the back protective sheet and the conductive substrates of the plurality of solar cells.

In another aspect is described a method of manufacturing a solar module, comprising: providing a front protective layer having a front surface and a back surface, wherein the front protective layer is transparent; placing a first encapsulant layer over the back surface of the front protective layer; placing a solar cell string over the first encapsulant layer, wherein the solar cell string includes a plurality of solar cells, each solar cell having a light receiving side and a back side, wherein the back side comprises a conductive substrate and wherein the plurality of solar cells are electrically interconnected in series using conductive leads which connect the light receiving side of one solar cell to the back side of an adjacent solar cell, and wherein the light receiving side of the solar cells face the first encapsulant layer; attaching a bypass diode device to the solar cell string, the bypass diode device including a first conductive strip and a second conductive strip each attached at one end to respective first and second leads of a bypass diode, wherein the bypass diode is electrically connected to a first conductive substrate of a first solar cell and a second conductive substrate of a second solar cell of the plurality of solar cells by the first conductive strip and the second conductive strip, respectively; placing a second encapsulant layer over the bypass diode device and the conductive substrates of the plurality of solar cells; placing a back protective sheet over the second encapsulant layer and sealing a peripheral gap between the periphery of the front protective sheet and the back protective sheet with a moisture barrier edge sealant, and thereby forming a pre-module structure; and subjecting the pre-module structure to heat and pressure to form the solar module.

### BRIEF DESCRIPTION OF THE DRAWINGS

FIG. 1 is a schematic view a thin film solar cell;

FIG. 2A is a schematic top view of a prior art photovoltaic module;

FIG. 2B is a schematic cross sectional view of the module of FIG. 2A;

FIGS. 3A-3C are schematic views of a photovoltaic module of the present invention including a bypass diode; and

FIG. 4 is a schematic bottom view of a solar cell string including bypass diodes.

FIG. 5A shows a side cross sectional view of a bypass diode device.

FIG. 5B is a top view of the bypass diode device of FIG. 5A.

FIG. 6A shows a pre-module structure with two solar cell strings.

FIG. 6B shows the pre-module structure of FIG. 6A after adding the bypass diode devices and buss conductors.

FIG. 6C shows a linear configuration of the bypass diode device placed on the back side of a solar cell string.

FIG. 6D shows a section of a long diode ribbon.

FIG. 7 shows a process sequence to fabricate a solar cell string including bypass diode devices.

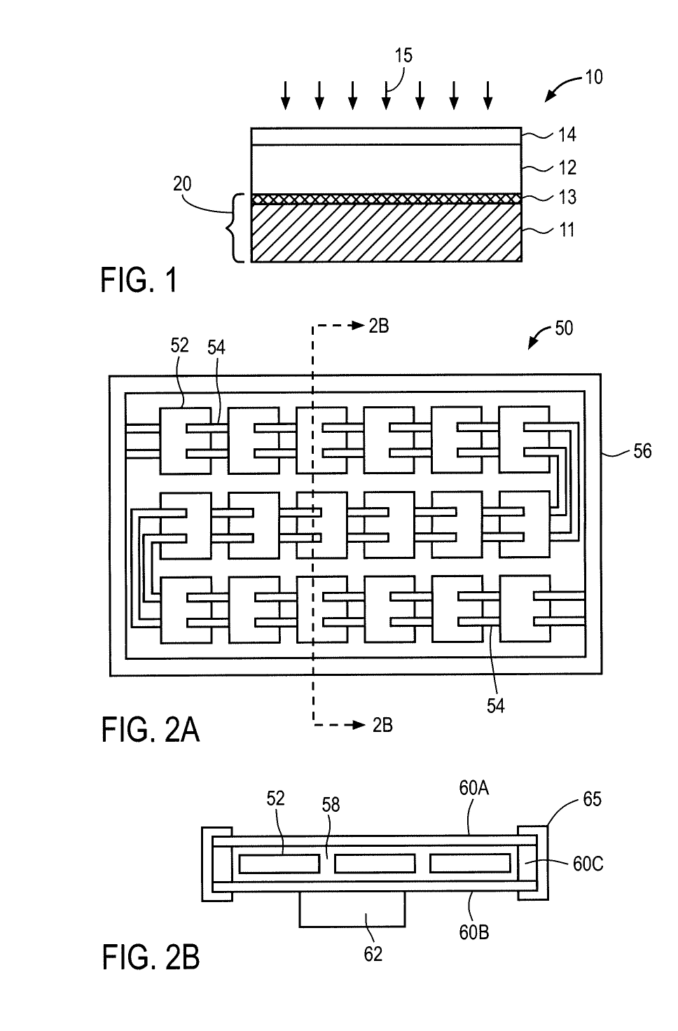

### DETAILED DESCRIPTION OF THE PREFERRED EMBODIMENTS

The preferred embodiments described herein provide module structures and methods of manufacturing rigid or flexible photovoltaic modules employing thin film solar cells fabricated on flexible substrates, preferably on flexible metallic foil substrates. The solar cells may be Group IBIIIAVIA compound solar cells fabricated on thin stainless steel or aluminum alloy foils. The modules each include a moisture resistant protective shell within which the interconnected solar cells or cell strings are packaged and protected. The protective shell comprises a moisture barrier top protective sheet through which the light may enter the module, a moisture barrier bottom protective sheet, a support material or encapsulant covering at least one of a front side and a back side of each cell or cell string. The support material may preferably be used to fully encapsulate each solar cell and each string, top and bottom. The protective shell additionally comprises a moisture sealant that is placed between the top protective sheet and the bottom protective sheet along the circumference of the module and forms a barrier to moisture passage from outside into the protective shell from the edge area along the circumference of the module. At least one of the top protective sheet and the bottom protective sheet of the present module may be glass for rigid structures. For flexible modules, the top and bottom protective sheets may be flexible materials that have a moisture transmission rate of less than 10⁻³ gm/m²/day, preferably less than 5×10⁻⁴ gm/m²/day.

In one embodiment, initially a solar cell string including two or more solar cells is formed by interconnecting the solar cells with conductive leads or ribbons. At least one bypass diode electrically connects conductive back surfaces of at least two solar cells, each solar cell having a back conductive surface and a front light receiving surface. The by pass diode and the solar cells are encapsulated with support material and are packed with the protective shell such that the at least one bypass diode is placed between at least one solar cell and the bottom protective sheet. The at last one bypass diode may be placed adjacent a central region of the back conductive surface of one of the solar cells. Further, the at last one bypass diode may be thermally connected to the back conductive surface of one of the solar cells so that the back conductive surface of the solar cell functions as a heat sink.

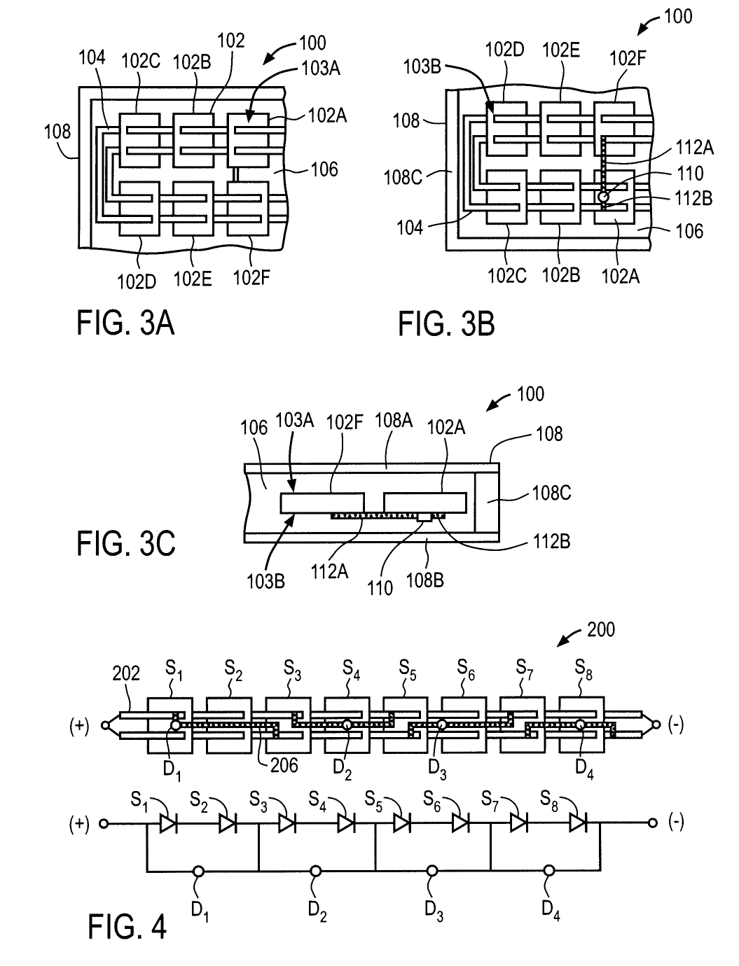

FIGS. 3A, 3B and 3C show partial top, bottom and cross sectional views of a module 100, respectively, which includes a solar cell string 102. It should be noted that top refers to the light receiving side of the module structure. The solar cell string 102 comprises solar cells 102A, 102B, 102C, 102D, 102E, and 102F which are interconnected in series with conductive leads 104 or ribbons. Each solar cell includes a light receiving front surface 103A and a back surface 103B. As shown in FIG. 3C, the string 102 is encapsulated with an encapsulation material 106 and placed in a protective shell 108 including a top protective sheet 108A, a bottom protective sheet 108B and an edge sealant 108C. The optional frame is not shown in this figure. In this example, a bypass diode 110 is placed over the back surface 103B of the solar cell 102A. The bypass diode 110 provides safe and efficient operation to the solar cells 102B, 102C, 102D, 102E and 102F that are interconnected. In one embodiment, the bypass diode 110 may be at a central location over the back surface of the solar cell 102A. The bypass diode 110 may be placed directly on the back surface 103B or it may be thermally coupled to the back surface by use of a thermal paste or adhesive. The thickness of the bypass diodes are typically less than 1.5 mm, preferably less than 1 mm. Diode leads 112A and 112B of the bypass diode 110 are electrically connected to the conductive leads 104 on the back sides 103B of the solar cells 102A and 102F. Alternately, the diode leads may be connected to the back surfaces 103B of the solar cells 102A and 102F since the back surfaces are metallic.

Many bypass diodes may be used, every two cells, every 3, 4, 5, or 6 cells or more. Bypass diodes are in the back of the cells and therefore, irrespective of how many are used, area utilization of the module is not reduced when observed from the top side. If the bypass diodes are along the edges of the module, that area is lost because it does not generate power. Therefore all packaging materials including glass, front sheet, back sheet, encapsulant or the like, used for that non-power generating area are wasted. Power density of the module (watts/meter squared) is reduced. Therefore, using thin bypass diodes on the back of the solar cells has many benefits.

Heat dissipation from bypass diodes is a reliability concern. When bypass diodes are placed in junction boxes outside the module package (as shown in FIG. 2B and described previously) they can be thermally coupled to structures that dissipate heat effectively. When they are laminated within the package itself, unless their heat can be dissipated they get hot and cause burning around them (hot spots). Encapsulants or support materials, as well as front and back protective sheets are not good thermal conductors since they are either polymeric materials or glass. Therefore, in such cases where diodes are used in typical glass solar cell modules, larger than necessary diodes may be used to avoid such heating problems. For example, for a module current rating of 3-4 amperes, a bypass diode with a current rating of 6-10 amperes may have to be used. This increases cost and also increased size of the bypass diodes makes the packaging processes challenging and increases area power loss of the module. The present invention, due to its use of a flexible structure that utilizes solar cells that are made on a metallic foil substrate, allows use of the metallic foil substrate as the heat sink for the bypass diodes. Thus, bypass diodes placed over the back surface of the metallic substrates of the solar cells may be thermally coupled to the solar cell substrates and any heat generated by the bypass diode can easily be dissipated to the large area solar cell and eventually to outside of the module. This also allows usage of bypass diodes that are sized to correspond to the module current rating, or some small percentage greater than the module current rating for reliability reasons, such as 10% or 20% larger. It should be noted that the typical size of the solar cells made on flexible substrates as described herein are larger than about 100 cm², whereas the typical size of the bypass diodes that correspond to the module current rating is less than 1 cm². Therefore, the cell provides excellent heat sink properties to the bypass diode. This increases the long term reliability of the module.

FIG. 4 shows the bottom (un-illuminated) side view of an exemplary solar cell string 200 containing eight linearly interconnected solar cells S1-S8. The solar cells S1-S8 may be CIGS solar cells fabricated on a metallic foil substrate such as a stainless steel substrate. The cells are serially interconnected using ribbons 202, and the solar cell string 200 has a (+) and a (−) terminal. In this example, bypass diodes D1, D2, D3 and D4 are connected in a way so that each bypass diode is connected across two serially connected solar cells. The electrical diagram 204 of the string 200 also shown in FIG. 4 shows the placement of solar cells S₁, S₂, S₃, S₄, S₅, S₆, S₇ and S_{g}, as well as the bypass diodes D₁, D₂, D₃ and D₄ in the circuit formed. The placements of the bypass diodes D1-D4 on the back side of the string 200 is intentionally varied to demonstrate various placement locations that may be practiced. For example, bypass diodes D1, D2 and D4 are placed at substantially the central locations on the back of solar cells S1, S2 and S4.

Although the above description provides a preferred implementation, it is also possible to place bypass diodes in a way that at least a portion of the bypass diode is thermally and physically coupled with the back side of a solar cell. Placement of the bypass diode D3 on the back side of cell S6 is an example of this embodiment. Bypass diodes may be connected to the back sides of the solar cells through connectors 206 or leads, which may be in the form of ribbons. A connector 206 may pass over the back surface of some solar cells to reach the back surface of the cell to which it needs to connect. For example, one connector of the bypass diode D1 in FIG. 4 has to travel over the back surface of solar cell S2 to reach the back surface of the solar cell S3 where it is electrically connected. Therefore, an insulating sheet may be used between the connector 206 and the back side of the solar cell S2 to avoid electrical short between the back side of the solar cell S2 and the connector 206.

Module structures that include flat bypass diodes placed between the solar cells and the back protective sheet of the module structure may be fabricated by various approaches that may be manual, semi-automated, or fully automated. In one approach, solar cell strings are formed using standard cell stringing techniques and the bypass diodes may be added to the strings after the formation of the strings, preferably during lay-up or bussing steps of module manufacturing. In another approach the bypass diodes may be integrated into the cell strings during the fabrication of the strings themselves as will be described later herein.

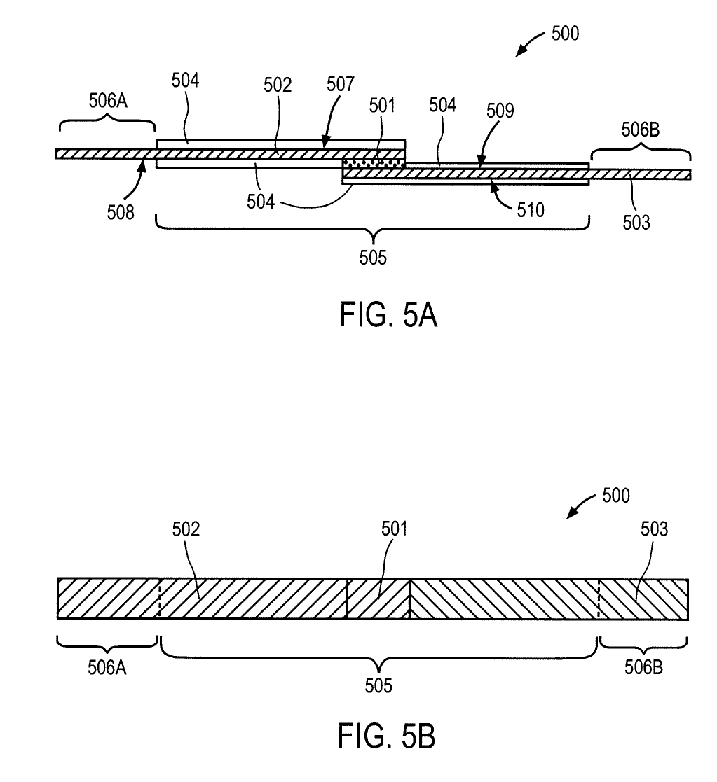

FIGS. 5A and 5B show the top and side views, respectively, of a preferred bypass diode device 500. The bypass diode device 500 has an active diode D in region 501 sandwiched between an upper lead 502 or connector that establishes a connection to one side of the diode pn junction and a lower lead 503 or connector that establishes a connection to the other side of the diode pn junction. The region 501 is where the rectifying junction of the diode D is located, and contains, as is conventionally known, both p-type and n-type semiconductor material to form the pn junction of the diode. The leads 502 and 503 are conductors which may have the same or different lengths and they are preferably in the form of thin and wide ribbons, such as copper ribbons. The ribbons may be coated with materials such as Ag, Sn, Sn—Ag alloys, low temperature alloys such as Bi containing alloys, etc. to make the leads easily attachable by soldering welding, etc. The typical thickness of the active diode region 501 may be in the range of 0.05-0.3 mm, which thickness includes both the p-type semiconductor layer and the n-type semiconductor layer. The thickness of the leads 502, 503 may be in the range of 0.1-0.4 mm making the overall thickness of the bypass diode device 500 less than about 1.5 mm, preferably less than about 1 mm. The width of the leads 502, 503 may be in the range of 1-10 mm depending on the current rating of the module within which the bypass diode devices D would be employed. The typical width of the leads 502, 503 may be in the range of 2-6 mm. Since the bypass diode devices D are placed on the bottom or back, un-illuminated side of the solar cells or the circuit, wide leads do not contribute to any power loss from the module.

As described with reference to FIG. 4, at least one of the upper lead 502 and the lower lead 503 of a bypass diode device 500 may be placed over the back surfaces of one or more interconnected solar cells and extended to the back surfaces of the two specific solar cells (from now on also called diode-connected cells) they need to be electrically connected to. To avoid electrical shorting between the leads 502 and 503 and the back sides of the solar cells between the two diode-connected cells, insulating films 504 may be placed on at least one of an upper surface 507 and lower surface 508 of the upper lead 502, and on at least one of an upper surface 509 and lower surface 510 of the lower lead 503, as needed. The insulating films 504 may be in the form of insulating sheets such as polymeric sheets that are 0.001-0.1 mm thick, or they may be electrically insulating adhesives to easily attach and secure the bypass diode devices onto the back surfaces of solar cells. The insulating films 504 may preferably be good thermal conductors to be able to dissipate the heat generated by the bypass diode in region 501 to the back surfaces of the solar cells onto which they are placed or mechanically attached. Use of insulating films 504 divides the bypass diode structure 500 into an electrically insulated region 505 where the leads are insulated from outside and two electrically conducting regions 506A and 506B, which in this example correspond to the two ends of the upper lead 502 and lower lead 503. Electrical connection of the bypass diode device 500 to the two diode-connected cells (such as cells S₁ and S₃, or S₃ and S₅, or S₅ and S₇ in FIG. 4) are made at the electrically conducting regions 506A and 506B, using methods such as soldering, welding (such as ultrasonic welding) or gluing (such as by conductive adhesives). It should be noted that although FIGS. 5A and 5B show one electrically insulated region and two electrically conducting regions, it is possible to design the bypass diode s with more electrically insulating and conducting regions.

### Example 1

### Adding Bypass Diodes to Already Formed Strings

In this approach, the solar cell strings, each having two or more solar cells, are first manufactured using various known methods and equipment. Tools that place solar cells, cut pieces of ribbons, and place pieces of ribbons in a way that form a solar cell string are designed and marketed by many companies such as GT-Solar and Spire of the USA. During stringing, the (+) terminal of a solar cell is connected to the (−) terminal of the adjacent solar cell, typically by one or more copper ribbon pieces. In cells with (+) and (−) terminals on two opposite sides (top and bottom sides) of the device, copper ribbon(s) are electrically connected to the top side or surface of one cell and to the bottom side or surface of the adjacent cell. In device structures where both (+) and (−) terminals are on the back or the bottom side of the solar cells, ribbons connect adjacent cells only on their back surfaces. In any case, typical cell strings may have 10-25 solar cells for high power module construction.

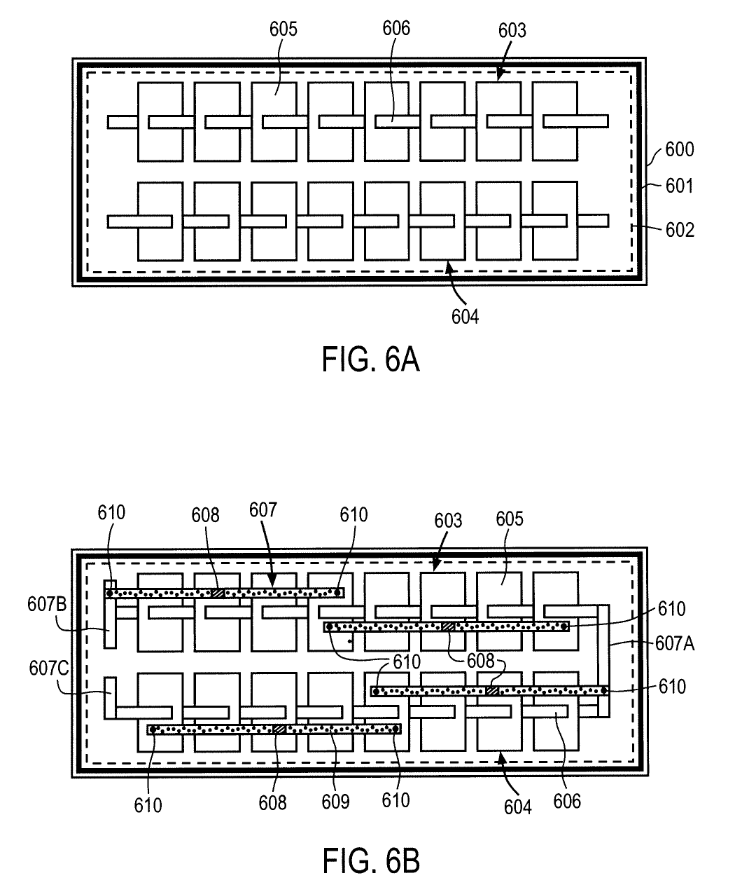

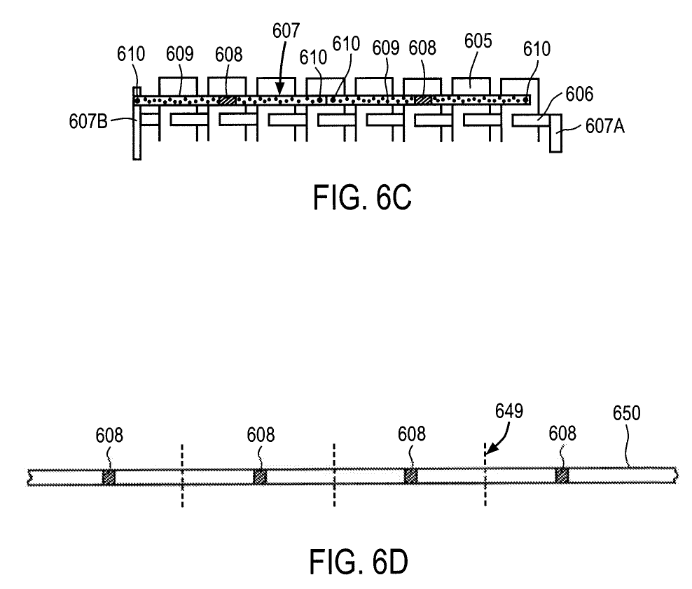

In one embodiment, once the cell strings are formed they are placed face down on a “top protective sheet/encapsulant sheet” stack at a “lay-up” station, and bypass diode device integration is performed during this lay-up step or the subsequent busing or bussing step of a typical module manufacturing approach. As shown in the example of FIG. 6A, during lay-up, the top protective sheet 600 is first placed on a flat surface. A first encapsulant sheet 602 such as EVA, silicone or TPU is placed over the top protective sheet 600. If needed, an edge sealant 601 is also placed along the circumference of the top protective sheet 600. Solar cell strings are then placed on the encapsulant sheet 602 in a face down manner, i.e. the illuminated top or front side of the solar cells facing the top protective sheet 600. The example in FIG. 6A shows the processing sequence for a module having two solar cell strings 603 and 604, each string having eight solar cells 605 interconnected serially using conductive ribbons 606.

The next step in module manufacturing process is typically called bussing and it involves interconnecting the solar cell strings to form a circuit. This is shown in FIG. 6B where the busbars or buss conductors 607A, 607B and 607C are attached to the conductive ribbons 606 at the two ends of the solar cell strings 603 and 604 to effectively connect the solar cell strings 603 and 604 in series. The buss conductors 607B and 607C in this design constitute the two terminals of the module and they are electrically connected to a junction box when the module construction is completed. Before, during or after the buss conductors 607A, 607B and 607C are configured and laid down, bypass diode devices 607 may be placed over the back surfaces of the solar cells 605. As described before, the bypass diode devices 607 have active diodes D in regions 608 and conductive leads 609, which are preferably in the form of thin ribbons. The bypass diode devices 607 are electrically connected to the buss conductors 607A and 607B, and to the back side of the specific solar cells (the diode-connected cells) at connection points 610 depending on a predetermined design. In the design of FIG. 6B the connection points 610 are selected so that each bypass diode device is across four solar cells in the module.

Electrical connection of the buss conductors 607A, 607B, 607C to the conductive ribbons 606 is typically achieved by welding or soldering at the bussing station, although conductive adhesives may also be used. Electrical connection of the bypass diode devices 607 at the connection points 610 may also be achieved by soldering or welding. However, use of conductive adhesives is preferred, especially if the solar cells 605 are thin film solar cells such as CIGS type solar cells fabricated on conductive substrates (such as stainless steel or aluminum alloy foils). In the next steps (not shown) of the process, a second encapsulant sheet in the preferred embodiment is placed over the solar cell circuit and the bypass diode devices in a way that it substantially aligns with the first encapsulant sheet 602. A bottom protective sheet may then be placed over the second encapsulant sheet in a way that substantially aligns it with the top protective sheet 600. Ends of the buss conductors 607B and 607C may be taken out through openings in the bottom protective sheet. This way a pre-module structure is obtained. The pre-module structure is then placed in a laminator or passed through a roll-to-roll laminator. The pre-module structure is converted into a module under heat and pressure applied by the laminator. Electrical connections to the exposed ends of the buss conductors 607B and 607C may then be made in a junction box placed on the bottom protective sheet and the module fabrication may be completed. A frame may optionally be placed around the circumference of the module. The back protective sheet may typically be a sheet of glass or a polymeric sheet such as TEDLAR®, or another polymeric material. The back protective sheet may comprise stacked sheets comprising various material combinations that will be described more fully below. The front protective sheet is typically a glass, but may also be a transparent flexible polymer film such as TEFZEL®, or another polymeric film. TEDLAR® and TEFZEL® are brand names of fluoropolymer materials from DuPont. TEDLAR® is polyvinyl fluoride (PVF), and TEFZEL® is ethylene tetrafluoroethylene (ETFE) fluoropolymer.

It should be noted that in one embodiment, the bypass diode devices 607 have at least one adhesive surface so that when they are placed over the back surfaces of the solar cells 605, they do not move around during handling and lamination. As described before, the adhesive layer may be electrically insulating but thermally conductive to transfer heat to the back side of the solar cells efficiently. If the electrical connection is carried out at the connection points 610 using a conductive adhesive, the conductive adhesive may be applied at the connection points 610 during the step of lay-up or bussing and the actual curing of the conductive adhesive may be achieved during the step of lamination. It should be noted that conductive adhesives typically need 120-170° C. curing temperature for a period of a few seconds to a few minutes. Typical lamination temperatures of 150-170° C. and lamination times of 1-15 minutes are adequate to laminate the module as well as cure the conductive adhesives to achieve the proper electrical integration of the bypass diode devices into the module. It should be noted that this approach of applying the conductive adhesive first and curing it during lamination may also be used to electrically connect the buss conductors 607A, 607B and 607C to the conductive ribbons 606.

Although FIG. 6B shows a very specific example for the electrical connection of the bypass diode devices 607, various other configurations are also possible. For example, instead of staggering the bypass diode devices 607, they can be placed in a co-linear fashion as shown in FIG. 6C, which depicts a portion of the structure in FIG. 6B with linearly placed bypass diode devices. Linearly placed bypass diode devices may be placed at any location over the back or bottom surface of the solar cells, including right over the conductive ribbons 606. For linear placement, it may desirable to have the bypass diode devices in the form of long ribbons or diode ribbon 650 as shown in FIG. 6D. The diode ribbon 650 may come on a spool in the form of a roll. During the manufacturing process bypass diode devices may be cut from the diode ribbon at appropriate locations shown as 649 and placed as described before. Although FIG. 6D shows cut locations 649 separating individual bypass diode devices, it is possible to cut the diode ribbon 650 such that the cut portion contains 2 or more bypass diode devices, which may be called bypass-diode strings. The bypass diode strings may then be attached to the backside of the solar cells in a linear fashion such as shown in FIG. 6C. For example, instead of attaching two separate bypass diode devices in FIG. 6C, one bypass diode string with two bypass diodes on it may be attached to the solar cell string. Such an approach is well suited for high throughput manufacturing and makes handling of the large number of bypass diode devices easier.

### Example 2

### Adding Bypass Diodes During Stringing of Solar Cells

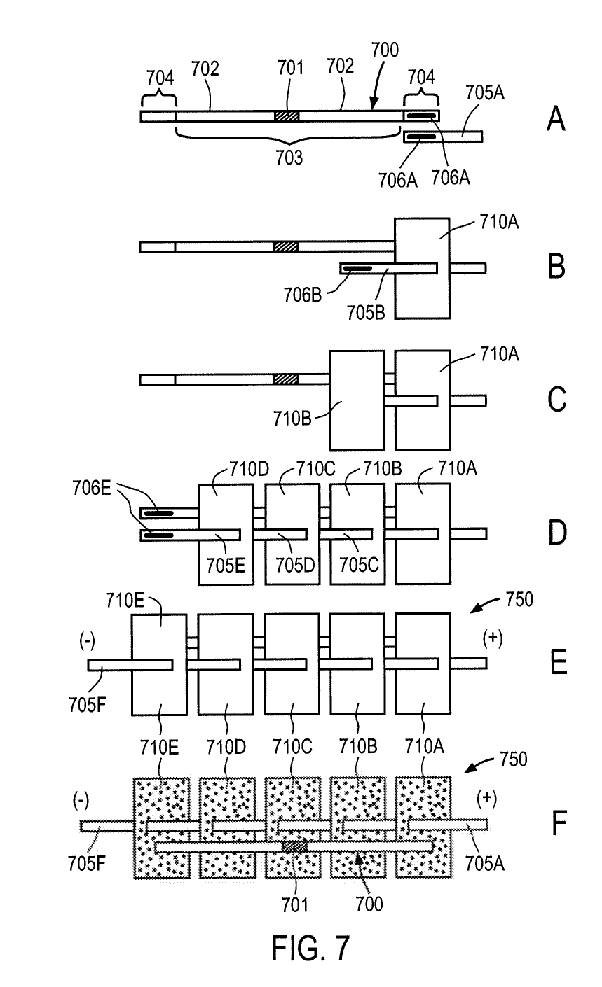

In this approach, as the solar cell strings, each having two or more solar cells, are manufactured, the bypass diode devices are integrated into the forming solar cell strings before the strings move to the lay-up station. In an example there is formed a five cell string with a bypass diode across four of the cells, where all electrical connections are made using a conductive adhesive. FIG. 7 shows an exemplary process flow for such a process. In a first step of the process flow (see FIG. 7-A) a bypass diode device 700 with an active diode D in region 701 and leads 702 is placed on a surface. The bypass diode device 700 may, for example, be cut from a diode ribbon such as the one depicted in FIG. 6D. The bypass diode device 700 may have an electrically insulated region 703 and two electrically conducting regions 704. A first conductive ribbon 705A is also placed on the surface. First conductive adhesive patches 706A are applied on the predetermined locations of the first conductive ribbon 705A and one of the electrically conductive regions 704 of the bypass diode device 700. A first solar cell 710A is placed over the first conductive ribbon 705A and the bypass diode device 700 as shown in FIG. 7-B. The first solar cell 710A is placed with its bottom or back surface towards the bypass diode device 700 so that the conductive adhesive patches 706A on the bypass diode device 700 as well as on the first conductive ribbon 705A make physical contact with the back surface of the first solar cell 710A. A second conductive ribbon 705B is then placed over the front surface of the first solar cell 710A using conductive adhesive (not shown) between the second conductive ribbon 705B and the top or illuminated surface of the first solar cell 710 A. A second patch of conductive adhesive 706B is applied on the second conductive ribbon 705B. It should be noted that although the conductive adhesives are shown to be applied on the ribbons and the bypass diode device in this example, it is also possible to dispense the conductive adhesives directly on the appropriate portions on the top or bottom surfaces of the solar cells. Also, although only one conductive ribbon is shown to interconnect two adjacent solar cells, two or more ribbons may also be used. Examples of thermally conductive adhesives include but are not limited to products sold by Resinlab (such as product No. EP 1121, which forms a flexible layer as desired in this application) and Dow Corning (such as product Nos. SE4450, 1-4173, and 3-6752). Thermally conductive transfer tapes provided by 3M company are also appropriate for this application

As shown in FIG. 7-C a second solar cell 710B is added to the string with the illuminated top surface of the device facing up. The process is repeated to add two more solar cells 710C and 710D to the string by adding a third conductive ribbon 705C, a fourth conductive ribbon 705D and a fifth conductive ribbon 705E to the structure. This way a four-cell string shown in FIG. 7D is obtained. Patches of conductive adhesive 706E are dispensed on the fifth conductive ribbon 705E and the bypass diode device 700 as shown in the figure. A fifth solar cell 710E and a sixth conductive ribbon 705F are provided to complete the five-cell string 750 shown in FIG. 7-E. The exemplary (+) and (−) terminals of the five-cell string 750 are shown for CIGS-type solar cells with conductive bottom surfaces. FIG. 7F shows the five-cell string 750 as viewed from the bottom side of the solar cells. In this configuration the bypass diode device 700 is across four solar cells (710A, 710B, 710C and 710D) with solar cells 710A and 710D being the diode-connected cells.

It should be noted that as solar cells and conductive ribbons are added to form a string, weights may be placed over the ribbons and the solar cells to keep them from moving around and to apply pressure on the conductive adhesive patches placed between various surfaces to assure good physical contact and good adhesion. The string, when completed may then be heated up to a curing temperature, for a curing period in the range of 1 second to 15 minutes. After curing, weights may be removed since the string becomes a well connected single piece that can be handled safely without causing cell or ribbon detachment. Solar cells in the above examples are only schematically shown to simplify the figures. The top surface of large area solar cells typically includes finger patterns. Such finger patterns are not shown in the figures.

The embodiments described herein are applicable to manufacturing modules using all classes of solar cells, including crystalline, polycrystalline and amorphous cells. However, they are especially suited for module manufacturing using thin film solar cells such as amorphous Si and Group IBIIIAVIA compound solar cells. Thin film solar cells fabricated on flexible foil substrates are flexible devices and they can be employed in flexible module structures. The bypass diode devices described herein are thin and flexible, and therefore are well suited for flexible module fabrication. In building integrated photovoltaics, the photovoltaic rooftop tile or rooftop membrane applications require flexible solar cells and module structures, which need to be especially protected from the negative effects of shadowing because cells on the roof are more prone to shadowing than the cells in field mounted PV modules. Consequently, roof integrated flexible modules may need by-pass diodes for every three cells, every two cells or even every cell for safe and efficient operation. The structures and methods of manufacturing discussed above are well suited for such applications. Also the bypass diode devices in the shape of ribbons are attractive for roll-to-roll manufacturing of flexible thin film modules such as CIGS-type modules with excellent bypass diode protection.

Although aspects and advantages of the present inventions are described herein with respect to certain preferred embodiments, modifications of the preferred embodiments will be apparent to those skilled in the art.

What is claimed is:

1. A solar module, comprising:
a solar cell string including a plurality of solar cells including a first solar cell and a second solar cell, each solar cell having a light receiving side and a back side, wherein the back side comprises a conductive substrate and wherein the plurality of solar cells are electrically interconnected in series using conductive leads which connect the light receiving side of one solar cell to the back side of an adjacent solar cell;
a bypass diode device attached to the solar cell string, the bypass diode device including a bypass diode having a first and second leads, and first and second conductive strips each electrically connected at one end to one of the first and second leads respectively and each electrically connected at another end to a first conductive substrate of the first solar cell and a second conductive substrate of the second solar cell, respectively;
an encapsulant having a frontside and a backside that encapsulates the solar cell string and the bypass diode device; and
a protective shell sealing the encapsulated string, the protective shell including a transparent front protective layer, a back protective layer and a moisture barrier seal extending between and sealing edges of the transparent front protective layer and the back protective layer, wherein the transparent front protective sheet is placed over the light receiving side of the plurality solar cells and the frontside of the encapsulant and the back protective sheet is placed under the first and second conductive substrates, the by pass diode device and the backside of the encapsulant such that the bypass diode is located between the back protective sheet and the conductive substrates of the plurality of solar cells.

2. The solar module of claim 1, wherein a thermal connection is established between the bypass diode device and one of the conductive substrates of the plurality of solar cells.

3. The solar module of claim 2, wherein the thermal connection is established by attaching the bypass diode device to one of the conductive substrates using one of a thermally conductive paste and thermally conductive adhesive.

4. The solar module of claim 3 wherein the of one the thermally conductive paste and thermally conductive adhesive directly attaches the bypass diode to one of the conductive substrates of the plurality of solar cells

5. The solar module of claim 2, wherein the thermal connection is established by directly mounting the bypass diode to one of the conductive substrates.

7. The solar module of claim 1, wherein the light receiving side of each solar cell includes one of a Group IBIIIAVIA thin film or a amorphous silicon thin film.

8. The solar module of claim 1, wherein the conductive substrate of each solar cell includes one of a stainless steel foil and aluminum foil.

9. The solar module of claim 1, wherein the encapsulant comprises at least one of ethylene vinyl acetate (EVA) and thermoplastic polyurethane (TPU).

10. The solar module of claim 1, wherein the transparent front protective layer comprises one of glass and ETFE (ethylene tetrafluoroethylene), and wherein the back protective layer comprises one of glass and PVF (polyvinyl fluoride).

11. A method of manufacturing a solar module, comprising:
providing a front protective layer having a front surface and a back surface, wherein the front protective layer is transparent;
placing a first encapsulant layer over the back surface of the front protective layer;
placing a solar cell string over the first encapsulant layer, wherein the solar cell string includes a plurality of solar cells, each solar cell having a light receiving side and a back side, wherein the back side comprises a conductive substrate and wherein the plurality of solar cells are electrically interconnected in series using conductive leads which connect the light receiving side of one solar cell to the back side of an adjacent solar cell, and wherein the light receiving side of the solar cells face the first encapsulant layer;
attaching a bypass diode device to the solar cell string, the bypass diode device including a first conductive strip and a second conductive strip each attached at one end to respective first and second leads of a bypass diode, wherein the bypass diode is electrically connected to a first conductive substrate of a first solar cell and a second conductive substrate of a second solar cell of the plurality of solar cells by the first conductive strip and the second conductive strip, respectively;
placing a second encapsulant layer over the bypass diode device and the conductive substrates of the plurality of solar cells;
placing a back protective sheet over the second encapsulant layer and sealing a peripheral gap between the periphery of the front protective sheet and the back protective sheet with a moisture barrier edge sealant, and thereby forming a pre-module structure; and
subjecting the pre-module structure to heat and pressure to form the solar module.

12. The method of claim 11, wherein the step of attaching the bypass diode device includes thermally connecting the bypass diode device to one of the conductive substrates of the plurality of solar cells.

13. The method of claim 12, wherein the thermal connection is established by attaching the bypass diode device to one of the conductive substrates using one of a thermally conductive paste and thermally conductive adhesive.

14. The solar module of claim 13 wherein the of one the thermally conductive paste and thermally conductive adhesive directly attaches the bypass diode to one of the conductive substrates of the plurality of solar cells

15. The method of claim 12, wherein the thermal connection is established by directly mounting the bypass diode to one of the conductive substrates.

16. The method of claim 11 further comprising the step of attaching a junction box to the back protective sheet after forming the solar module.

17. The method of claim 11, wherein the step of subjecting the pre-module structure to heat and pressure is performed in a roll-to-roll laminator.

18. The method of claim 11, wherein the light receiving side of each solar cell includes one of a Group IBIIIAVIA thin film or a amorphous silicon thin film.

19. The method of claim 11, wherein the conductive substrate of each solar cell includes one of a stainless steel foil and aluminum foil.

20. The method of claim 11, wherein the encapsulant layer comprises at least one of ethylene vinyl acetate (EVA) and thermoplastic polyurethane (TPU).

21. The method of claim 1, wherein the front protective layer comprises one of glass and ETFE (ethylene tetrafluoroethylene), and wherein the back protective layer comprises one of glass and PVF (polyvinyl fluoride).
